(19) United States
(12) Patent Application Publication
(10) Pub. No.: US 2012/0254686 A1
(43) Pub. Date: Oct. 4, 2012

(54) NON-VOLATILE SEMICONDUCTOR MEMORY DEVICES AND ERROR CORRECTION METHODS

(75) Inventors: Atsushi ESUMI, Yokohama (JP); Kai Li, Yokohama (JP)

(73) Assignee: SIGLEAD Inc., Kanagawa (JP)

(21) Appl. No.: 13/249,751

(22) Filed: Sep. 30, 2011

(30) Foreign Application Priority Data
Oct. 1, 2010 (JP) 2010-223839

(51) Int. Cl. H03M 13/05; G06F 11/10

(52) U.S. Cl. 714/763; 714/E11.034

(57) ABSTRACT

An error correction unit is an area in a page where the error bit count is low, and an error correction unit is an area in a page where the error bit count is high. The error correction unit includes a user data area, a first redundancy area, and a second redundancy area. The error correction unit includes a user data area, a first redundancy area, and a second redundancy area. Errors in the user data areas are corrected with a first set of redundant bits stored in the first redundancy areas, respectively. A second set of redundant bits for correcting errors in the user data area within the high-error bit count page is stored in the second redundancy area within the low-error bit count page and the second redundancy area within the high-error bit count page in a distributed manner.

### BACKGROUND OF THE INVENTION

1. Field of the Invention

The present invention relates to a data structure of a non-volatile semiconductor memory, and a method and a device for correcting errors using such data structure.

2. Description of the Related Art

Non-volatile semiconductor memories called flash memories are becoming smaller in size and larger in terms of their capacity. Such flash memories have a storage area including a plurality of uniformly sized blocks, and each block includes a plurality of uniformly sized pages. Data are erased from a flash memory on a block-by-block basis, and read out of and written into a flash memory on a page-by-page basis.

Flash memories have gained larger storage capacity through miniaturization and multi-level cell technology. A side effect of larger storage capacity is an increasing number of error bits. It is a common practice to correct errors with the use of an error correcting code (ECC). Examples of error correcting codes include BCH codes, Reed-Solomon codes, and low-density parity-check (LDPC) codes.

In a flash memory, each page stores error correcting codes. An example is illustrated in FIG. 19. Section 700 is one of four sections into which one page is divided. In other words, four sections 700 placed side by side constitute a single page. Each section 700 is made up of a user data area 701 and a redundancy area 702 in which an error correcting code that is capable of, for example, 24-bit error correction, is stored. User data are stored in the user data area 701, and the size of the user data area 701 is, for example, 1 kilobyte. Redundant bits of an error correcting code are stored in the redundancy area 702, and the size of the redundancy area 702 may, for example, be 336 bits. Error correction performance is improved when the size of the redundancy area 702 is larger. The number of redundant bits is on the rise as the memory cells rely on multi-level technologies and miniaturization, or as reliability has to be improved. On the other hand, an increase in size of the redundancy area 702 also increases the size of the circuitry for error correction. This increase in circuit size means a smaller area for memory packaging and results in a smaller storage capacity. The increased number of redundant bits or the increased size of the redundancy area 702 also leads to increased time required for reading and reproducing user data that are stored in the user data area 701.

As a possible solution to this problem, Japanese Provisional Patent Publication (JP A) H11-143787 discloses a semiconductor memory in which error correction circuits are provided both inside and outside a memory chip.

JP A 2009-211742 describes an error correction circuit that does not execute error correction when the detected error bit count is higher than its error correction capability in order to avoid further adding error bits.

JP A 2008-108297 describes a non-volatile semiconductor storage device improved in error correction efficiency by mixing a high-error rate portion with a low-error rate portion in a single ECC frame and thus evening out location-dependent fluctuations in error rate among ECC frames.

### SUMMARY OF THE INVENTION

In view of problems associated with the related art, the present invention provides a novel error correction method and error correction device for a non-volatile semiconductor memory.

It is an object of the present invention to accomplish an error correction method and an error correction device that focus on the pattern of error bit occurrence in a non-volatile semiconductor memory to keep the size of an error correction circuit small and make a better use of an area which is used to store error correcting codes.

First, patterns of the occurrence of bits that contain an error are described with reference to FIGS. 1 and 2. FIG. 1 is a graph in which the axis of abscissa shows the page number and the axis of ordinate shows the count of error bits. In the example of FIG. 1, the error bit count is approximately 120 at most in each of pages 0 to 120. In pages 120 to 127, on the other hand, the error bit count per page is approximately 370 at maximum and approximately 150 at minimum. In short, the error bit count is low in most pages and is equal to or higher than a given count only in pages that have larger page numbers. As in this example, there are normally several pages show high error bit counts, and many other pages have low error bit counts. Pages in which the error bit count is high tend to localize at the beginning and end of a block, and are not distributed throughout the block.

Two types of errors occur while writing and reading to and from a memory device: an error in which the bit value of a bit that is actually “0” is mistaken for “1”, and an error in which the bit value of a bit that is actually “1” is mistaken for “0.” Hereinafter, the former is referred to as minus (−) error and the latter is referred to as plus (+) error. The pattern of occurrence of those two types of errors is illustrated in FIG. 2. FIG. 2 is a graph in which the axis of abscissa shows the page number, the axis of ordinate in the positive direction shows the count of plus errors, and the axis of ordinate in the negative direction shows the count of minus errors. A line connecting the minus error counts is denoted by symbol C1 and a line connecting the plus error counts is denoted by symbol C2. As can be seen in FIG. 2, the plus error count is very low in a page where the minus error count is high, and the minus error count is very low in a page where the plus error count is high. When this is considered on a page-by-page basis, minus errors and plus errors hardly occur at the same frequency in one page, and the count of one of the two types of errors tends to be extremely higher than the count of the other, irrespective of how high or low the error bit count itself is.

FIG. 3 is a graph schematically showing, for each page, the distribution of the count of error bits that are corrected with conventional error correction by reading a page that contains error bits. The size of the redundancy area is determined with a page that has a high count of error bits as a reference, and accordingly excess redundant bits are actually attached to many pages. In short, the redundancy area has not been utilized for the best use of its potential because most of pages contain relatively small numbers of error bits. The present invention has been made by paying attention on this error bit occurrence pattern and the utilization of space for redundancy areas.

First, the present invention provides a non-volatile semiconductor memory device having a storage area containing a plurality of pages, each of which includes at least one error correction unit comprising a user data area and a redundancy area, wherein the redundancy area of the at least one error correction unit comprises: a first redundancy area for storing a first set of redundant bits for correcting errors in the user data area within the error correction unit; and a second redundancy area for storing a second set of redundant bits for correcting errors in the error correction unit in order to deal with a case where a relatively large number of errors in a first page to which the error correction unit belongs, so that the second set of redundant bits may be distributed between the error correction unit and an error correction unit in at least one different page which has a relatively small number of errors compared to the first page.

The present invention also provides an error correction method for a non-volatile semiconductor memory device having a storage area containing a plurality of pages, each of which comprises at least one error correction unit comprising a user data area and a redundancy area, wherein the redundancy area of the at least one error correction unit comprises: a first redundancy area for storing a first set of redundant bits for correcting errors in the user data area within the error correction unit; and a second redundancy area for storing a second set of redundant bits for correcting errors in the error correction unit when it is known that a relatively large number of errors exist in a page to which the error correction unit belongs, so that the second set of redundant bits may be distributed between the error correction unit and an error correction unit in a different page having a small number of errors compared to the page to which the error correction unit belongs, the error correction method comprising the steps of: correcting, with the first set of redundant bits, errors in user data of an error correction unit that belongs to a page having a relatively small number of errors; and dividing a user data area for user data of an error correction unit that belongs to a page having a relatively large number of errors, and performing error correction on each area that is created by dividing the user data area with redundant bits in the second redundancy area.

The present invention also provides an error correction method for a non-volatile semiconductor memory device having a storage area containing a plurality of pages comprising a page having a relatively small number of errors and a page having a relatively large number of errors, each of the plurality of pages including at least one error correction unit which comprises a user data area and a redundancy area, wherein the redundancy area of at least one error correction unit found in at least one page having a relatively small number of errors comprises: a first redundancy area for storing a first set of redundant bits for correcting errors that are in the user data area within the at least one error correction unit; and a second redundancy area for storing a second set of redundant bits for correcting errors in an error correction unit that belongs to a page having a relatively large number of errors, wherein the redundancy area of at least one error correction unit in at least one page having a relatively large number of errors stores at least one set of redundant bits for correcting errors in a user data area within the at least one error correction unit, the error correction method comprising: a first correction step of correcting errors in the user data area of the at least one error correction unit in the at least one page having a relatively large number of errors, with the at least one set of redundant bits in the at least one error correction unit; a post-correction state determination step of determining whether or not the errors in user data within the at least one error correction unit have successfully been corrected in the first correction step; and an error correction step of dividing, when it is determined in the post-correction state determination step that the errors have not been corrected successfully, the user data area of the at least one error correction unit, and performing error correction on each area that is created by dividing the user data area, with the redundant bits in the second redundancy area, or all or part of redundant bits other than those in the set of redundant bits found in the at least one error correction unit of the at least one page having a relatively large number of errors, or both.

The error correction method may further include, prior to the first correction step, an error detection step of detecting errors in the user data of the error correction unit; and a step of determining whether or not the errors detected in the error detection step are correctable in the first correction step, so as to proceed to the first correction step when the errors are correctable, and otherwise proceed to the second correction step.

In the error detection step, errors may be detected by converting user data and redundant bits each into a balanced code in which the count of “0” bits and the count of “1” bits are made equal to each other, writing the balanced codes in the non-volatile semiconductor memory device, reading the balanced codes out of the non-volatile semiconductor memory device, and utilizing a loss of the balance between the count of “0” bits and the count of “1” bits in order to detect an error.

The present invention also provides an error correction device for a non-volatile semiconductor memory device having a storage area containing a plurality of pages, each of which includes at least one error correction unit comprising a user data area and a redundancy area, the error correction device comprising: first redundant bit writing means for storing, in an error correction unit, a first set of redundant bits for correcting errors in user data of that error correction unit; second redundant bit writing means for storing a second set of redundant bits for correcting errors in the one error correction unit when a relatively large number of errors exist in the user data of the one error correction unit, so that the second set of redundant bits may be distributed between the one error correction unit and an error correction unit that belongs to a different page having a relatively small number of errors compared to a page to which the one error correction unit belongs; first error correction executing means for correcting error bits in the one error correction unit with the first set of redundant bits; post-correction state determining means for determining whether or not the first error correction executing means has succeeded in correcting the errors in the user data of the one error correction unit; and second error correction executing means for using the second set of redundant bits to correct error bits in the one error correction unit when the post-correction state determining means determines that the errors have not been corrected successfully.

The error correction device may further include error detecting means for detecting a count of error bits in the one error correction unit; and correction method determining means for determining whether or not the error bit count detected by the error detecting means is within a range that is correctable by the first error correction executing means, and, when the correction method determining means determines that the detected errors are correctable by the first error correction executing means, the first error correction executing means can execute error correction, and otherwise the second error correction executing means can execute error correction.

The error detecting means may convert user data and redundant bits each into a balanced code in which a count of “0” bits and a count of “1” bits are made equal to each other, write and read the balanced codes in and out of the non-volatile semiconductor memory device, and utilize a loss of balance between the count of “0” bits and the count of “1” bits so as to detect an error.

The present invention also provides a non-volatile semiconductor memory device including a storage area including a plurality of pages including relatively low-error count/proportion pages and relatively high-error count/proportion pages, the plurality of pages each including at least one error correction unit, which includes a user data area and a redundancy area, in which the redundancy area of at least one error correction unit that is in at least one relatively low-error count/proportion page includes: a first redundancy area for storing a first set of redundant bits for correcting errors that are in the user data area within the at least one error correction unit; and a second redundancy area for storing at least part of a second set of redundant bits for correcting errors in an error correction unit that belongs to a relatively high-error count/proportion page.

An error correction unit of a relatively high-error count/proportion page to be corrected and a location where redundant bits used for the correction of the error correction unit are saved may be associated with each other based on a given rule. For example, the error correction of an error correction unit in one page uses redundant bits contained in an error correction unit at a corresponding point in a page (relatively low-error count/proportion page) that precedes or follows the one page by a given count of pages. The relation between an error correction unit and a storage location of its redundant bits is arbitrary and not limited to a particular example.

The present invention also provides an error correction method for a non-volatile semiconductor memory device including a storage area including a plurality of pages including relatively low-error count/proportion pages and relatively high-error count/proportion pages, the plurality of pages each including at least one error correction unit, which includes a user data area and a redundancy area, the redundancy area of at least one error correction unit that is in at least one relatively low-error count/proportion page including: a first redundancy area for storing a first set of redundant bits for correcting errors that are in the user data area within the at least one error correction unit; and a second redundancy area for storing a second set of redundant bits for correcting errors in an error correction unit that belongs to a relatively high-error count/proportion page, the error correction method including: a first correction step of correcting errors in a user data area of an error correction unit that belongs to a relatively low-error count/proportion page, with the first set of redundant bits in the error correction unit; and a second correction step of dividing a user data area of an error correction unit that belongs to a relatively high-error count/proportion page, and performing error correction on each area that is created by dividing the user data area, with one or both of redundant bits in the second redundancy area and all or part of redundant bits in the error correction unit of the relatively high-error count/proportion page.

As another embodiment, the present invention provides an error correction method for a non-volatile semiconductor memory device including a storage area including a plurality of pages including relatively low-error count/proportion pages and relatively high-error count/proportion pages, the plurality of pages each including at least one error correction unit, which includes a user data area and a redundancy area, the redundancy area of at least one error correction unit that is in at least one relatively low-error count/proportion page including: a first redundancy area for storing a first set of redundant bits for correcting errors that are in the user data area within the at least one error correction unit; and a second redundancy area for storing a second set of redundant bits for correcting errors in an error correction unit that belongs to a relatively high-error count/proportion page, the redundancy area of at least one error correction unit in at least one relatively high-error count/proportion page storing at least one set of redundant bits for correcting errors in a user data area within the at least one error correction unit, the error correction method including: a first correction step of correcting errors in the user data area of the at least one error correction unit in the at least one relatively high-error count/proportion page, with the at least one set of redundant bits in the at least one error correction unit; a post-correction state determination step of determining whether or not errors in user data within the at least one error correction unit have successfully been corrected in the first correction step; and an error correction step of dividing, when it is determined in the post-correction state determination step that the errors have not been corrected successfully, the user data area of the at least one error correction unit, and performing error correction on each area that is created by dividing the user data area, with one or both of redundant bits in the second redundancy area and all or part of other redundant bits in the at least one error correction unit of the at least one relatively high-error count/proportion page than the at least one set of redundant bits.

The present invention also provides an error correction method for a non-volatile semiconductor memory device including a storage area including a plurality of pages including relatively low-error count/proportion pages and relatively high-error count/proportion pages, the plurality of pages each including at least one error correction unit, which includes a user data area and a redundancy area, the user data area of at least one error correction unit in a relatively high-error count/proportion page including a particular area, the redundancy area of at least one error correction unit that is in at least one relatively low-error count/proportion page including: a first redundancy area for storing a first set of redundant bits for correcting errors that are in the user data area within the at least one error correction unit; and a second redundancy area for storing a second set of redundant bits for correcting errors in the particular area within an error correction unit that belongs to a relatively high-error count/proportion page, the redundancy area of at least one error correction unit in at least one relatively high-error count/proportion page storing at least one set of redundant bits for correcting errors in a user data area within the at least one error correction unit, the error correction method including: a first correction step of correcting errors in the user data area of the error correction unit in the relatively high-error count/proportion page, with the at least one set of redundant bits in the error correction unit; a post-correction state determination step of determining whether or not errors in user data within the error correction unit have successfully been corrected in the first correction step; an error correction step of applying the second set of redundant bits to the particular area when it is determined in the post-correction state determination step that the errors have not been corrected successfully; and a correction step of replacing data in the particular area with the corrected data of the particular area, and thereafter correcting errors in the user data area that contains the replacement data, with the one set of redundant bits in the error correction unit.

### BRIEF DESCRIPTION OF THE DRAWINGS

In the accompanying drawings:

FIG. 1 is a graph showing the relation between the page number and the error bit count;

FIG. 2 is a graph showing the relation between the page number and the plus error count and the minus error count;

FIG. 3 is a graph schematically showing for each page the distribution of the count of error bits that are corrected by error correction;

FIG. 4 is a diagram illustrating a first example of the data structure of the unit of error correction which is used when redundant bits are stored in a distributed manner;

FIG. 5 is a diagram illustrating a second example of the data structure of the unit of error correction which is used when redundant bits are stored in a distributed manner;

FIG. 6 is a diagram illustrating a third example of the data structure of the unit of error correction which is used when redundant bits are stored in a distributed manner;

FIG. 7 is a block diagram of a solid state drive (SSD) according to the present invention;

FIG. 8 is a block diagram of an error correction coding portion;

FIG. 9 is a diagram illustrating a fourth example of the data structure of the unit of error correction which is used when redundant bits are stored in a distributed manner;

FIG. 10 is a diagram illustrating a fifth example of the data structure of the unit of error correction which is used when redundant bits are stored in a distributed manner;

FIG. 11 is a graph comparing four types of error correction in terms of error correction performance;

FIG. 12 is a flow chart of error correction that employs two sets of error correcting codes;

FIG. 13 is a block diagram of an error correction decoding portion for performing error correction that employs two sets of error correcting codes;

FIG. 14 is a flow chart of error correction in which an error is corrected by choosing one of two sets of error correcting codes after executing advance determination;

FIG. 15 is a block diagram of an error correction decoding portion that further includes advance determination means;

FIG. 16 is a diagram illustrating error detection that uses a balancing code;

FIG. 17 is a graph showing the difference in throughput between the case where advance determination is executed and the case where advance determination is not executed;

FIG. 18 is a diagram illustrating an example of the data structure of the unit of error correction which is used when redundant bits are stored in a distributed manner, and a flow chart of error correction that uses the unit of error correction of this example; and

FIG. 19 is a diagram illustrating a conventional data structure.

### DETAILED DESCRIPTION OF THE PREFERRED EMBODIMENT

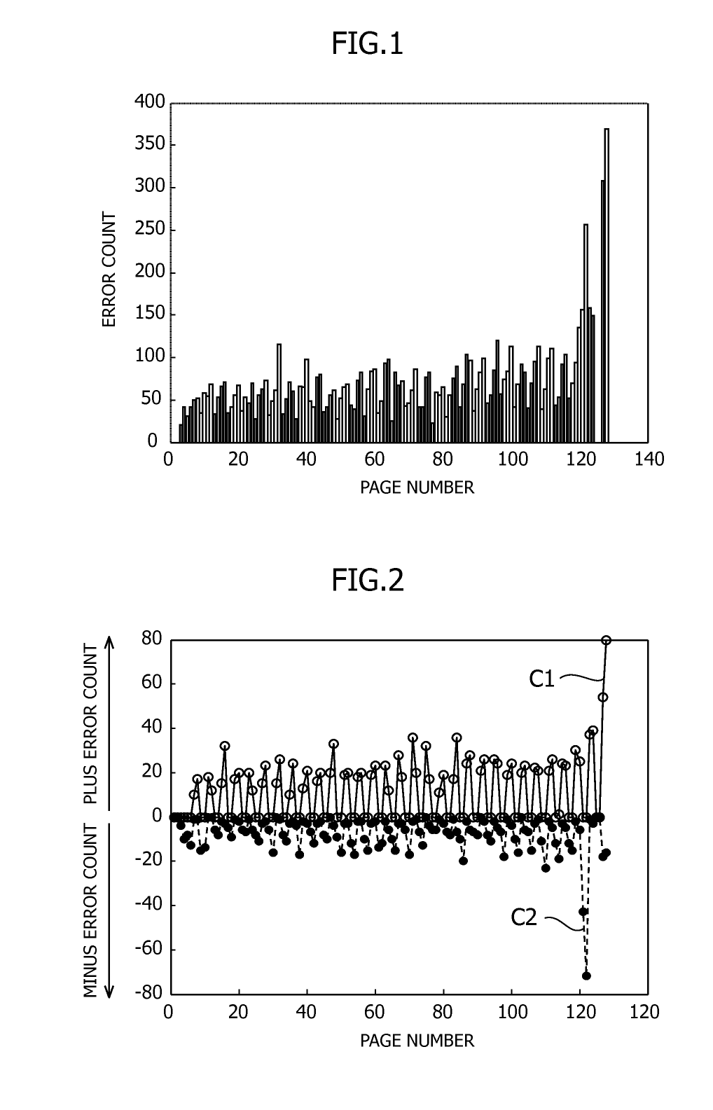

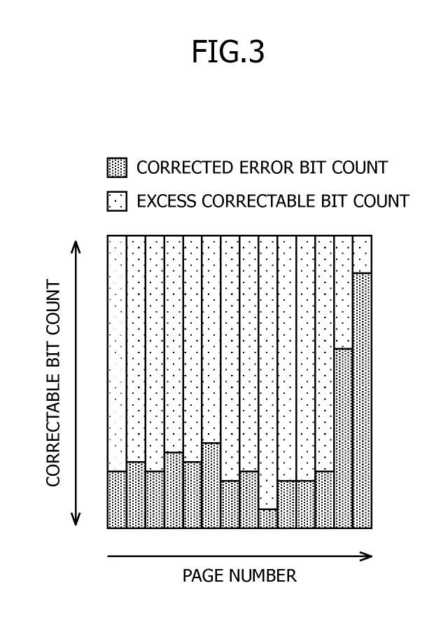

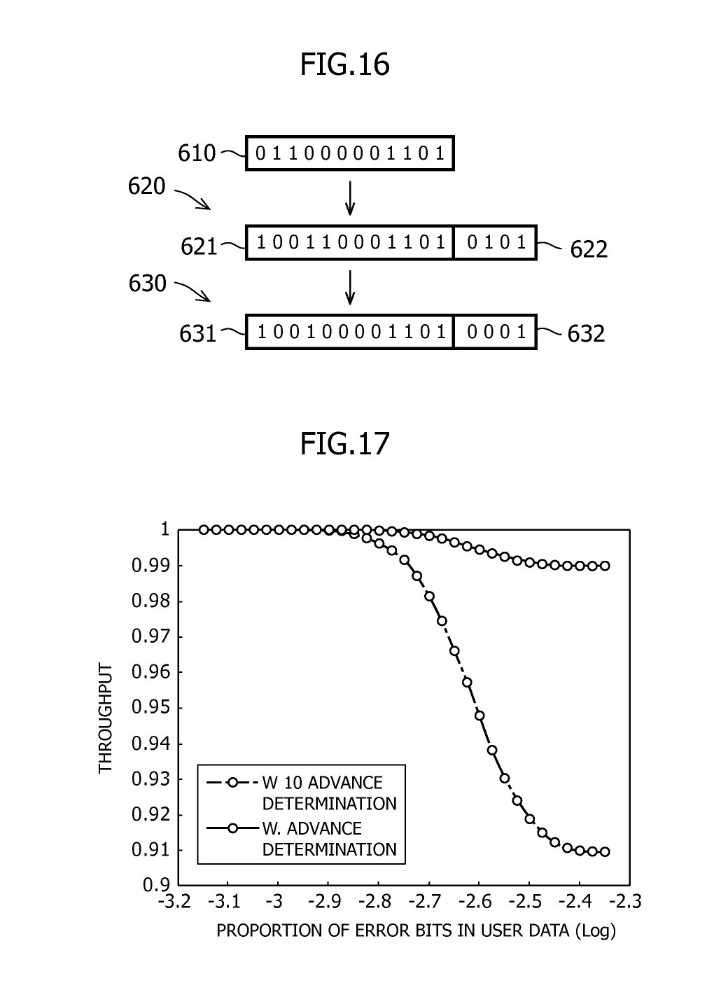

In view of the bit error occurrence pattern described with reference to FIGS. 1 to 3, it is preferred to vary error correction performance between pages where the error bit count is high and pages where the error bit count is low. Specifically, FIG. 16 illustrates an example in which correction performance is set for 24-bit error correction, and let us consider how to enhance the correction performance. When the correction performance is enhanced from 24-bit error correction to, for example, 60-bit error correction, the enhancement is accompanied by an increase in complexity of an error correction circuit. Therefore, let us consider using error correction in which correction performance is set for 20-bit error correction and error correction in which correction performance is set for 41-bit error correction to keep the complexity of an error correction circuit from increasing much. The description here gives the numerical values of correction performance such as 20-bit, 41-bit, and 60-bit error correction as an example, and the present invention is not restricted by those numerical values.

First error correction, where correction performance is high enough for 20-bit error correction with respect to 1 kilobyte of user data, is applied to pages that have a relatively low error count (good pages). Second error correction uses an error correcting code capable of 41-bit error correction with respect to 512 bytes of user data obtained by dividing 1 kilobyte of user data in two. The second error correction is applied to pages that have a relatively high error count (bad pages). BCH is used as an example of an error correction method. The former is written as BCH (20, 1024) and the latter is written as BCH (41, 512). In other words, BCH (A, B) means that a BCH method capable of A-bit error correction is applied to B bytes of user data. The correction performance of BCH (41, 512) is four times the correction performance of BCH (20, 1024) or more.

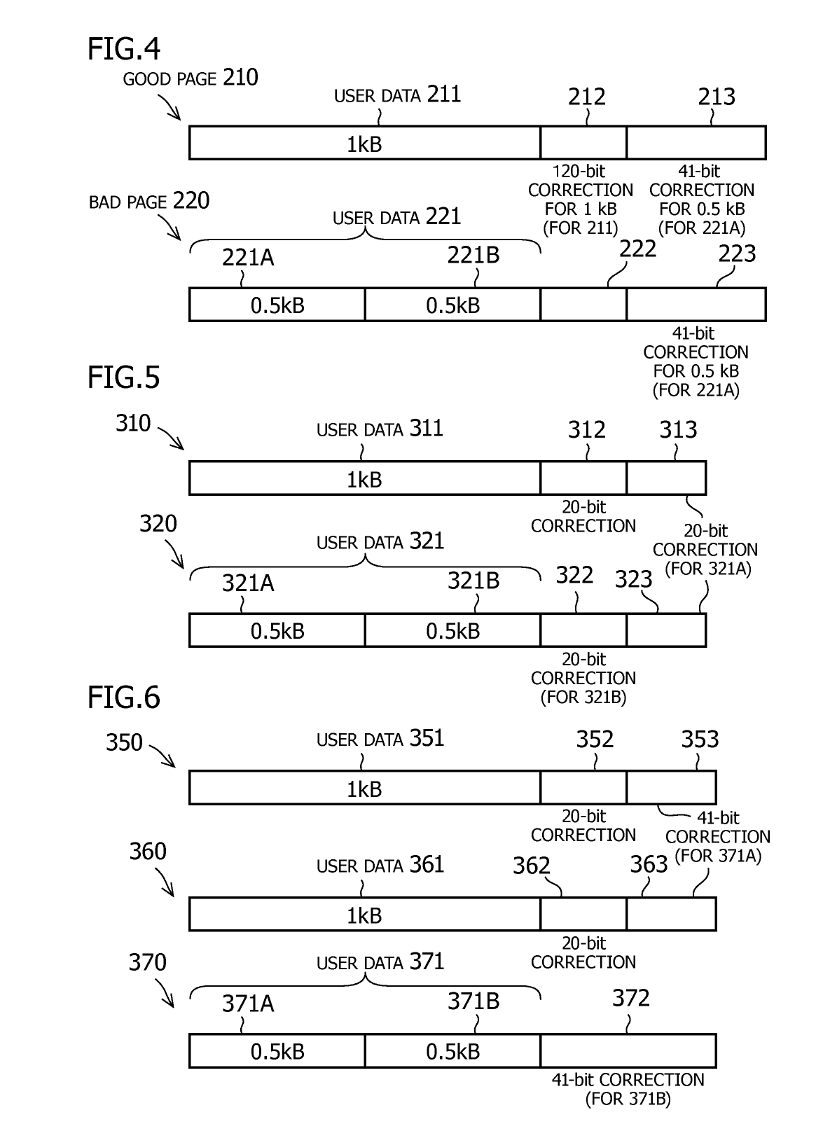

FIG. 4 illustrates the usage of page areas for error correction that uses BCH (20, 1024) and BCH (41, 512). Here, an error correction unit 210 is an area within a page that has a low error bit count (good page) and an error correction unit 220 is an area within a page that has a high error bit count (bad page). The error correction unit 210 includes a user data area 211, which is 1 kilobyte in size, a first redundancy area 212 for 20-bit error correction, and a second redundancy area 213 for 41-bit error correction. The error correction unit 220 has the same structure as that of the error correction unit 210, and includes a user data area 221, a first redundancy area 222, and a second redundancy area 223. The error correction units 210 and 220 are areas present in one block. The two may be in pages next to each other, but do not need to be in adjacent pages and one page or a plurality of pages may be interposed between the two. The relation between a page having a high error bit count and a page having a relatively low error bit count where redundant bits used for the correction of the page having a high error bit count are saved is not determined by a fixed rule but by an arbitrary rule.

In the error correction unit 210, the first redundancy area 212 stores a first set of redundant bits used for the first error correction, namely, BCH (20, 1024), to correct errors in the user data area 211. The second redundancy area 213 stores a second set of redundant bits used for the second error correction, namely, BCH (41, 512), to correct errors in the first half of the user data area 221 in the page with a high error bit count which is a user data area 221A (512 bytes).

In the error correction unit 220, the first redundancy area 222 stores the first set of redundant bits used for the first error correction, namely, BCH (20, 1024), to correct errors in the user data area 221. The second redundancy area 223 stores the second set of redundant bits used for the second error correction, namely, BCH (41, 512), to correct errors in the latter half of the user data area 221 in the error correction unit 220 which is a user data area 221B. In short, the second set of redundant bits for correcting errors in the user data area 221 within the error correction unit 220 of a page with a high error bit count is stored in the second redundancy areas 213 and 223 in a distributed manner.

This way, a redundancy area made up of the second redundancy areas 213 and 223 can be secured for the user data area 221 of 1 kilobyte of high-error bit count user data. To elaborate, the second redundancy area for 41-bit error correction can be secured for each of the areas 221A and 221B (each having 512 bytes) which constitute the user data area 221. In addition, the redundancy area 212 or 213, which has been wasted in the related art, is made full use of. Specifically, instead of applying redundant bits for 60-bit error correction to all pages, redundant bits for 20-bit error correction are applied to a normal page whereas errors in a page with a high error bit count are corrected by dividing the user data area of the page in two and using redundant bits for, for example, 41-bit error correction on each half of the user data area. This significantly cuts down the size of a circuit necessary for error correction, from a 60-bit circuit to a 41-bit circuit.

Similarly, in the case of FIG. 5 where an error correction unit 310 is in a page that has a relatively low error bit count and an error correction unit 320 is in a page that has a relatively high error bit count, BCH (20, 1024) is used to correct errors in a 1-kilobyte user data area 311 within the error correction unit 310 of the relatively low-error bit count page. A redundancy area 312 for this correction is therefore provided. As defined above, the redundancy area 312 provides correction performance high enough for 20-bit error correction. BCH (20, 512) may be used to correct errors in each of a half user data area 321A and another half user data area 321B in the error correction unit 320 of the page with a relatively high error bit count. In this case, redundant bits for BCH (20, 512) can be divided in two to correct the half user data area 321A, and can be saved separately as an area 313 and an area 323, which are in the error correction unit 310 and the error correction unit 320, respectively. For the other half user data area 321B, redundant bits for BCH (20, 512) can be saved in an area 322, which corresponds to the area 312. To correct errors in the area 321A, redundant bits saved in the area 313 and redundant bits saved in the area 323 are combined. In this case, only a 20-bit circuit is required.

Let us consider another case of FIG. 6 where error correction units 350 and 360 are in a page that is relatively low in error bit count and an error correction unit 370 is in a page that is relatively high in error bit count. BCH (20, 1024) is used to correct errors in a 1-kilobyte user data area 351 within the error correction unit 350 of the relatively low-error bit count page, and a redundancy area 353 for this correction is therefore provided. The same applies to the error correction unit 360. Redundant areas 352 and 362 each provide correction performance high enough for 20-bit error correction. A user data area 371 of the error correction unit 370 in the page having a relatively high error bit count is divided into two 0.5-kilobyte areas, which are an area 371A and an area 371B. Redundant bits for BCH (41, 512) used to correct errors in the user data area 371A are divided between the error correction units 350 and 360 of the relatively low-error bit count page. Redundant bits used to correct errors in the user data area 371B can be contained in an area 372 within the error correction unit 370 of the page having a relatively high error bit count.

At least some of redundant bits for user data correction can thus be placed in a distributed manner outside an error correction unit within a page having a relatively high error bit count, in other words, inside an error correction unit within a relatively low-error bit count page. The redundant bits can be distributed in any way as long as a given rule is followed. While a user data area in a page having a relatively high error bit count is divided in two to create two equal-sized areas in the examples of FIGS. 4 to 6, this is given as an example and the user data area can be divided at an arbitrary ratio such as 2:3 or 3:4. The user data area may also be divided into four or more areas or into an odd number of areas such as three areas as in the following examples.

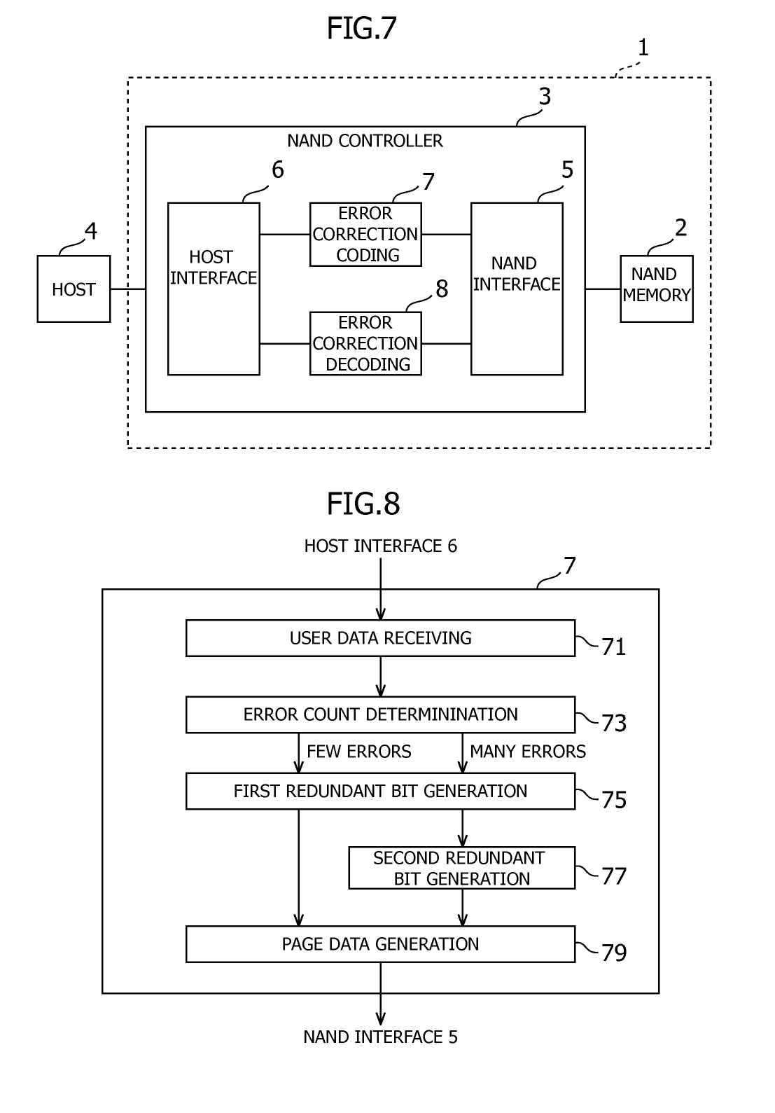

FIG. 7 is a block diagram schematically illustrating a solid state drive (SSD) 1 according to an embodiment of the present invention. The SSD 1 is connected to a host device 4 to function as an external memory of the host device 4. The SSD 1 includes a NAND flash memory (hereinafter, referred to as NAND memory) 2 as a non-volatile memory, and a NAND controller 3, which reads/writes data from/to the NAND memory 2 in response to an instruction of the host device 4. The storage area of the NAND memory 2 includes a plurality of uniformly-sized blocks and each block includes a plurality of uniformly-sized pages as described above. The non-volatile memory used in this embodiment is a NAND memory, but the present invention is not limited thereto.

The NAND controller 3 of FIG. 7 includes a host interface 6, which performs interface processing to interface the NAND controller 3 with the host device 4, a NAND interface 5, which performs interface processing to interface the NAND controller 3 with the NAND memory 2 and read/write data, an error correction coding portion 7, which generates an error correcting code for data written in the NAND memory 2, and an error correction decoding portion 8, which detects and corrects errors in data read out of the NAND memory 2.

As illustrated in FIG. 8, the error correction coding portion 7 includes user data receiving means 71 for receiving user data from the host device 4, error count determining means 73 for determining whether or not a page of the NAND memory 2 in which data is about to be written is a page having a high error bit count, first redundant bit generating means 75, second redundant bit generating means 77, and page data generating means 79. The first redundant bit generating means 75 generates a first set of redundant bits for correcting errors in user data of the NAND memory 2 by the error correction unit 210 described above. The first set of redundant bits is made up of redundant bits used for the first error correction, for example, BCH (20, 1024). The second redundant bit generating means 77 generates a second set of redundant bits for correcting errors in user data of the NAND memory 2 by the error correction unit 220 described above when the error correction unit is to be written in a page having a high error bit count. The second set of redundant bits is made up of redundant bits used for the second error correction, for example, BCH (41, 512). Whether or not a page in which data is about to be written is a page having a high error bit count may be determined from stored results of a test which has been conducted, or from stored results of the past write or read. In this case, actively providing the second redundancy area also for pages where the error count is not so high enables the error correction coding portion 7 to deal with the rise of error rate with time and other similar problems more flexibly.

The page data generating means 79 divides user data received from the host device 4 into pieces of a given size (1 kilobyte, for example) to generate a user data piece to be written in the user data area 211 of FIG. 4. The page data generating means 79 combines this user data piece with the first set of redundant bits generated by the first redundant bit generating means 75 and the second set of redundant bits generated by the second redundant bit generating means 77 to create data of the error correction unit 210. The page data generating means 79 also divides user data received from the host device 4 into pieces of a given size (512 bytes, for example) to generate user data pieces to be written in the user data areas 221A and 221B of FIG. 4. The page data generating means 79 combines those two user data pieces with the first set of redundant bits generated by the first redundant bit generating means 75 and the second set of redundant bits generated by the second redundant bit generating means 77 to create data of the error correction unit 220. The page data generating means 79 generates the data of the error correction units 210 and 220 such that the second set of redundant bits for the user data to be written in the user data area 221A is contained in the data of the error correction unit 210 whereas the second set of redundant bits for the user data to be written in the user data area 221B is contained in the data of the error correction unit 220.

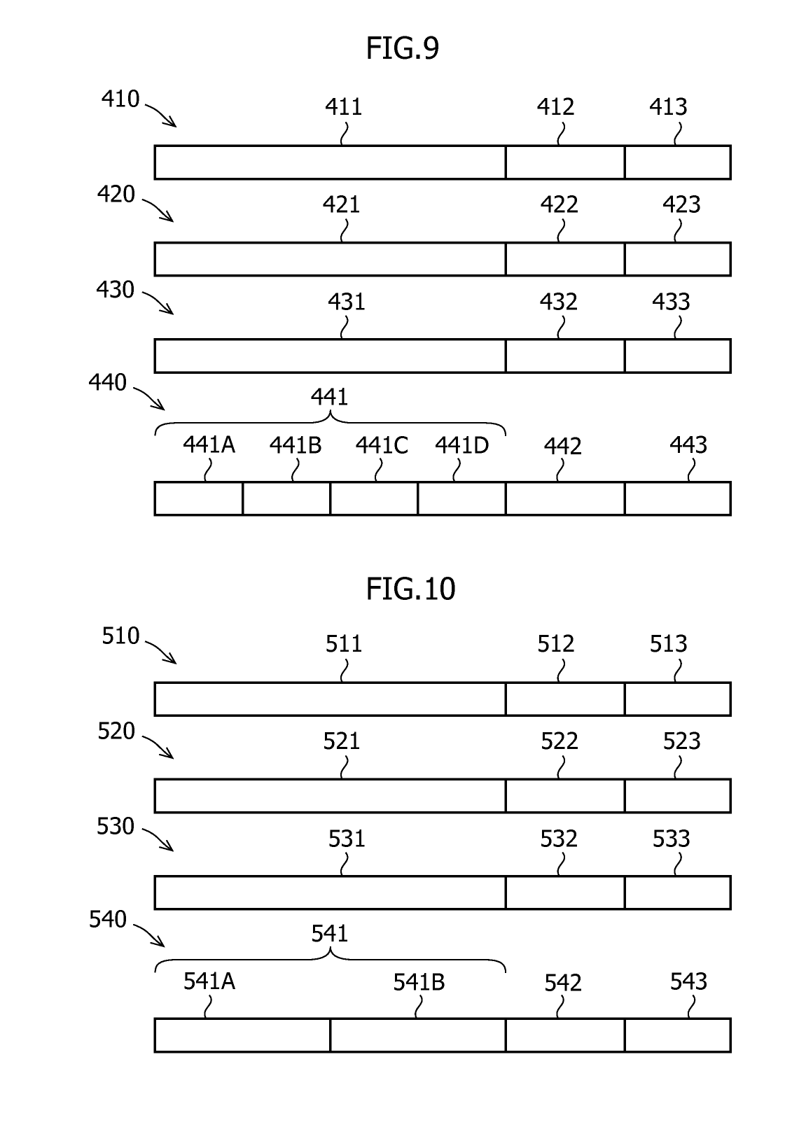

FIG. 9 illustrates still another modification example of FIG. 4. Error correction units 410, 420, and 430 each belong to a page where the error bit count is low. An error correction unit 440 belongs to a page where the error bit count is high. As in the examples described above, those four error correction units can have any positional relation with one another as long as the error correction units 410, 420, and 430 and the error correction unit 440 belong to different pages. First redundancy areas 412, 422, 432, and 442 store redundant bits used for the first error correction of user data areas 411, 421, 431, and 441, respectively. Redundant bits used for the second error correction of areas 441A, 441B, 441C, and 441D (each having a size of 256 bytes) within a user data area 441 in the error correction unit 440 of the page having a high error bit count are respectively stored in second redundancy areas 413, 423, 433, and 443 in a distributed manner. The first error correction and the second error correction in FIG. 9 are, for example, BCH (31, 1024) and BCH (29, 256), respectively. The correction performance of BCH (29, 256) is approximately 3.7 times the correction performance of BCH (31, 1024).

FIG. 10 illustrates yet still another modification example of FIG. 4. Error correction units 510, 520, and 530 each belong to a page where the error bit count is low. An error correction unit 540, on the other hand, belongs to a page where the error bit count is high. A user data area 541 within the error correction unit 540 includes two areas (each having a size of 512 bytes), an area 541A and an area 541B. As in the examples described above, those four error correction units can have any positional relation with one another as long as the error correction units 510, 520, and 530 and the error correction unit 540 belong to different pages. First redundancy areas 512, 522, 532, and 542 store redundant bits used for the first error correction of user data areas 511, 521, 531, and 541, respectively. Redundant bits used for the second error correction of the area 541A in the error correction unit 540 of the page having a high error bit count are stored in second redundancy areas 533 and 543 in a distributed manner. Redundant bits used for the second error correction of the area 541B are stored in second redundancy areas 513 and 523 in a distributed manner. The first error correction and the second error correction are, for example, BCH (31, 1024) and BCH (50, 512), respectively. The correction performance of BCH (50, 512) is approximately 3.2 times the correction performance of BCH (31, 1024).

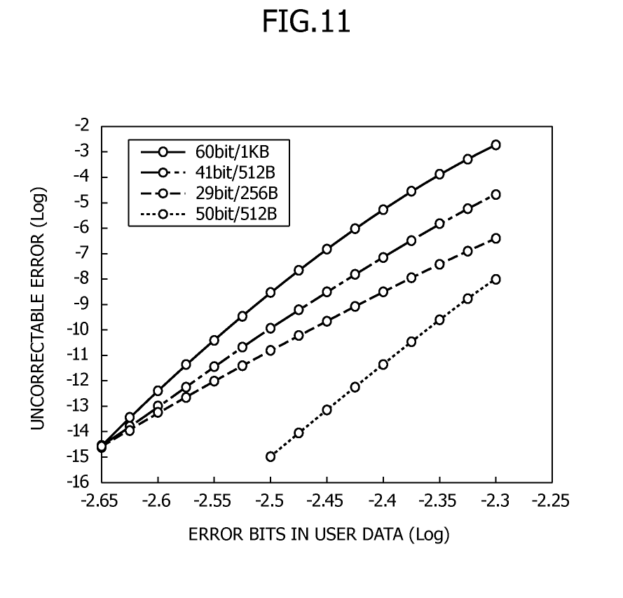

FIG. 11 is a graph comparing four types of correction methods, specifically, BCH (60, 1024), BCH (41, 512), BCH (29, 256), and BCH (50, 512), in terms of correction performance. The axis of abscissa shows the proportion of errors in original user data and the axis of ordinate shows the proportion of error bits that remain after error correction. Four curves in the graph respectively represent the four methods, BCH (60, 1024), BCH (41, 512), BCH (29, 256), and BCH (50, 512). The graph shows that, in all of the four methods, the proportion of error bits that have failed to be corrected is higher when the proportion of error bits in original user data is higher. The current standard for tolerable error proportion is around 10⁻¹³. According to the standard, the performance of BCH (29, 256) where the circuit scale is small is better than the performance of BCH (60, 1024) where the circuit scale is large, as can be seen in the graph. The graph also shows that the performance of BCH (50, 512) is excellent despite the method being smaller in circuit scale than BCH (60, 1024).

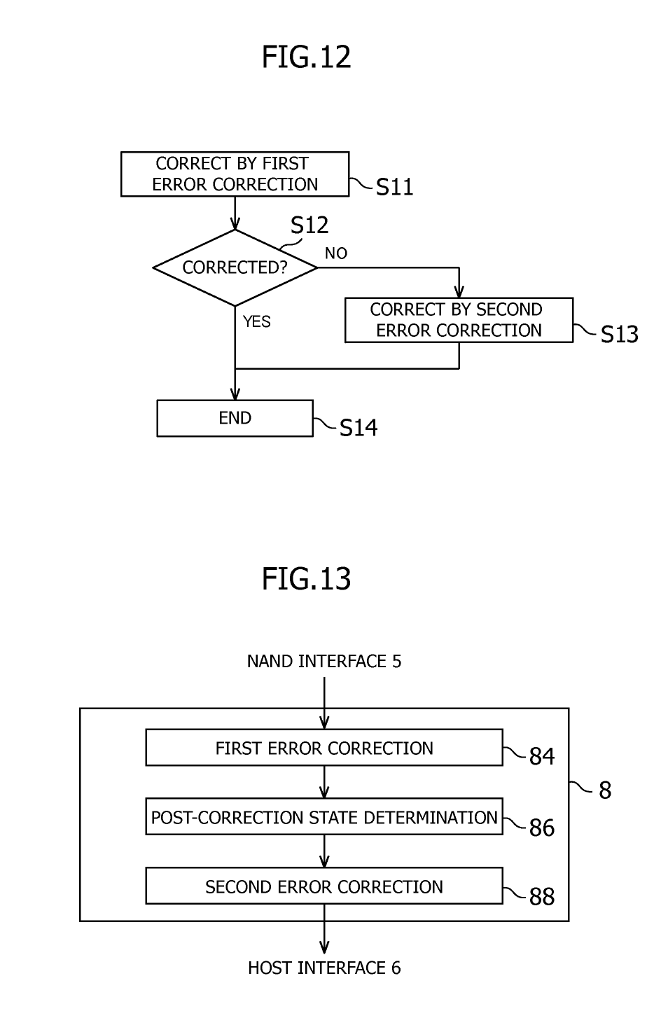

FIG. 12 is a flow chart of error correction that uses two sets of error correcting codes in the form of redundant bits that are stored in a distributed manner as illustrated in FIGS. 4, 5, 6, 9, and 10. FIG. 13 is a block diagram of the error correction decoding portion 8 that executes processing illustrated in the flow chart of FIG. 12. The error correction decoding portion 8 includes first error correction executing means 84, post-correction state determining means 86, and second error correction executing means 88 as illustrated in FIG. 13.

First, the first error correction executing means executes error correction in Step S11 using the first error correction method. In Step S12, the post-correction state determining means 86 determines whether or not errors have been corrected successfully. Specifically, whether or not errors have been corrected successfully is determined from an “uncorrectable” signal of a decoder. In this case, errors are determined as “successfully corrected” when, for example, BCH capable of 41-bit error correction reduces the error bit count in the unit of the BCH (e.g., 512 bytes) to 41 bits or less. When the answer to Step S12 is “Yes,” the processing ends in Step S14. When the answer to Step S12 is “No,” the processing proceeds to Step S13, where the second error correction executing means 88 executes error correction using the second error correction method which has higher correction performance. The processing then ends in Step S14.

Through the processing flow of FIG. 12, errors are corrected by using two sets of error correcting codes for each error correction unit that has the data structure of FIG. 4, 5, 6, 7, or 8. Errors are therefore corrected efficiently in both of pages with a high error bit count and those with a low error bit count. However, because the second error correction is executed to correct errors that have failed to be corrected by the first error correction, this processing also has a drawback in that performing two types of error correction on a single page lowers the throughput.

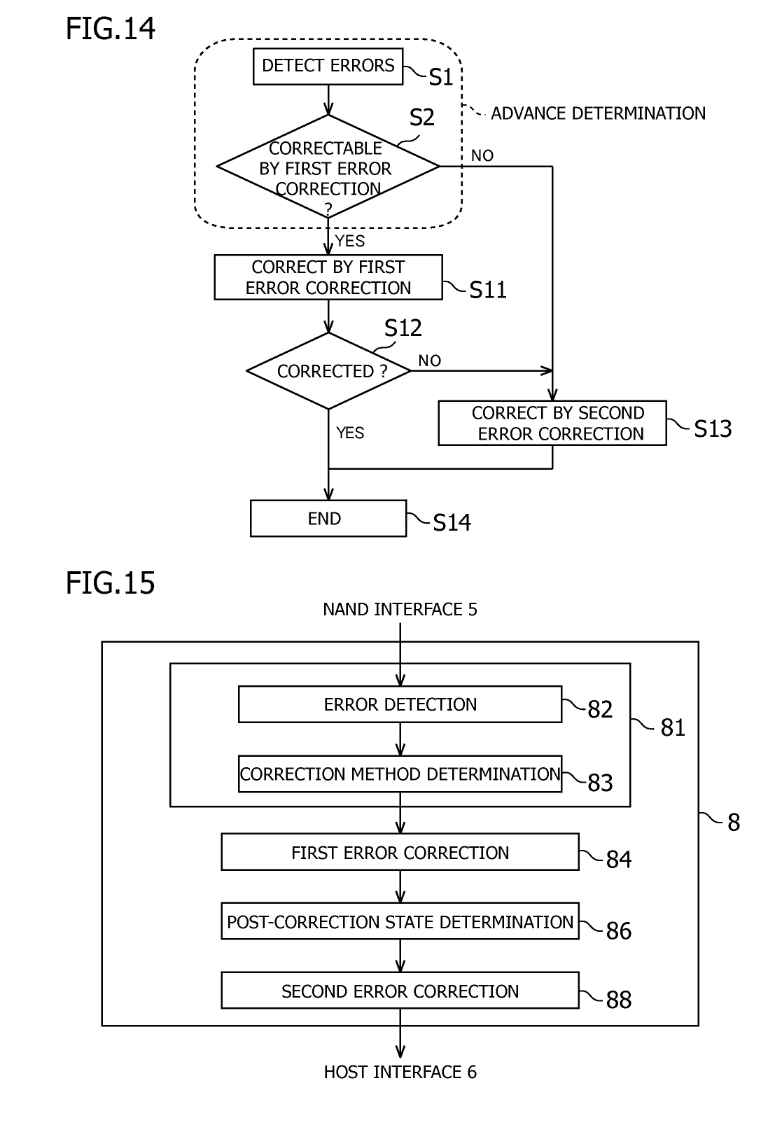

FIG. 14 is a flow chart of error correction using two sets of error correcting codes that overcomes this drawback. Steps in FIG. 14 that are common with those in FIG. 12 are denoted by the same symbols. FIG. 15 is a block diagram of the error correction decoding portion 8 that executes processing illustrated in the flow chart of FIG. 14. Components in FIG. 15 that are common with those in FIG. 13 are denoted by the same symbols. FIG. 15 differs from FIG. 13 in that the error correction decoding portion 8 includes advance determination means 81. The advance determination means 81 includes error detecting means 82 and correction method determining means 83.

First, the error detecting means 82 detects errors in Step S1. Details thereof are described later. In Step S2, the correction method determining means 83 determines whether or not the errors detected by the error detecting means 82 are correctable by the first error correction method. The first error correction (ECC1) method is desirably BCH that is relatively low in error correction performance, for example, BCH (20, 1024). When the answer to Step S2 is “Yes,” the processing proceeds to Step S11. When the answer to Step S2 is “No,” the processing proceeds to Step S13.

According to the processing flow of FIG. 14, the error detecting means 82 detects errors in Step S1, and the first error correction executing means 84 executes the first error correction only when the correction method determining means 83 determines in Step S2 that the detected errors are correctable by the first error correction. Otherwise, the second error correction executing means 88 executes the second error correction which is high in correction performance. In other words, the advance determination means 81 performs advance determination, which includes Steps S1 and S2 of FIG. 14, before error correction is executed. Error correction is therefore executed only once for each page and the problem described above about the lowering of throughput is avoided.

The specific flow of the error detection in Step S1 of FIG. 14 is described with reference to FIG. 16. Denoted by symbol 610 is a part of a bit string of original user data. The bit count of bit string 610 is 12 bits, of which 5 bits have a bit value “1” and the remaining 7 bits have a bit value “0.” Balancing processing is applied to bit string 610. The balancing processing is to convert a bit string into another bit string that has equal numbers of “1” and “0” bits, if the original bit string does not have equal numbers of “0” and “1”, and a code obtained as a result of the balancing processing is called a balanced code which always has equal number of “1” and “0” bits. Details thereof are described in Donald E. Knuth, “Efficient Balanced Codes,” IEEE Transactions on Information Theory, IEEE January 1986, Vol. IT-32, No. 1, pp. 51-53. Specifically, parameter K is determined for bit string 610, and the first K bits are inverted. Here, K is set to 5, and the first five bits “01100” of bit string 610 are inverted into “10011,” thereby obtaining another bit string 621. In bit string 621, the count of bits having bit value “1” and that for bit value “0” are both 6. This bit string 621 is called a balanced code. Following bit string 621, a 4-bit parity bit 622 is provided. The bit value of parity bit 622 is “0101” which is obtained by expressing parameter K set to 5 in the form of binary number, and this is also a balanced code in which the count of “0” bits and the count of “1” bits are equal. Having such a parity bit, how many bits counted from the head of the string have been inverted in bit value may be found. Bit string 620 which is made up of bit string 621, which is a balanced code, and parity bit 622, also a balanced code, is also a balanced code. In bit string 620, the count of bits having a bit value “1” and the count of bits having a bit value “0” are both 8. It has been proven that parameter K exists in any bit string. For details thereof, see Donald E. Knuth, “Efficient Balanced Codes,” IEEE Transactions on Information Theory, IEEE January 1986, Vol. IT-32, No. 1, pp. 51-53.

In the example of FIG. 16, the parity bit 622 itself happened to be a balanced code which is a binary expression of parameter K. However, a bit string obtained by expressing parameter K in the form of binary number may not always be a balanced code, depending on the value of parameter K. For instance, if the value of parameter K is 7, its binary expression is “0111”. The bit string “0111” is not a balanced code and cannot be used as the parity bit 622 as it is. As a solution, a rule that turns the bit string “0111” into a code “1010” which is a balanced code may be defined in advance and saved as a lookup table. This way, whatever value parameter K has, a parity bit that is a balanced code can be derived from parameter K. This method using a lookup table is merely an example and any other methods can be employed as long as the method ensures that parameter K expressed in the form of binary number is a balanced code.

Bit string 620 constituted of bit strings 621 and 622 is written in a page, and the result of reading bit string 620 out of the page is bit string 630. Bit string 630 includes bit strings 631 and 632. In bit string 630, the count of bits having a value “1” is 6 bits and the count of bits having a value “0” is 10 bits. In a comparison between bit strings 620 and 630, the count of bits having a value “1” has decreased from 8 bits to 6 bits, which means that plus errors have occurred in two bits. By performing this conversion into a balanced code on every bit string of original user data and then writing the bit string to a page, errors can be detected easily in the manner of Step S1. The error detection in Step S1 may also use conventional detection methods instead of the method that uses a balanced code. Specifically, the employed error detection method may be one in which soft information (reliability information) is used when user data is read to count low-reliability bits.

In the case where minus and plus errors have occurred the same number of times during the writing of bit string 620 into a page, the count of bits having a bit value “1” has not changed before and after the writing, and errors cannot therefore be detected. This is because error detection is made by simply comparing the counts of bits having a bit value “1” in bit strings 620 and 630. However, minus errors and plus errors occurring the same number of times is a rarity in practice as described above with reference to FIG. 2, and the simple error detection using a balanced code can therefore be employed.

FIG. 17 is a graph showing the difference in throughput between the case where the advance determination means 81 has executed advance determination constituted of Steps S1 and S2 and the case where the advance determination has not been executed. In FIG. 17, BCH (20, 1024) is used as the first error correction method and BCH (41, 512) is used as the second error correction method. The axis of abscissa shows the proportion of error bits in user data written in a user data area, and the axis of ordinate shows the throughput. Curves respectively represent the case where the advance determination has not been executed and the case where the advance determination has been executed. As can be seen in the graph, when the proportion of error bits in the user data is higher, the throughput drops significantly in the case where the advance determination has not been executed whereas the throughput remains stable at a high level in the case where the advance determination has been executed. In fact, the throughput in the case where the advance determination has been executed does not drop lower than 0.99.

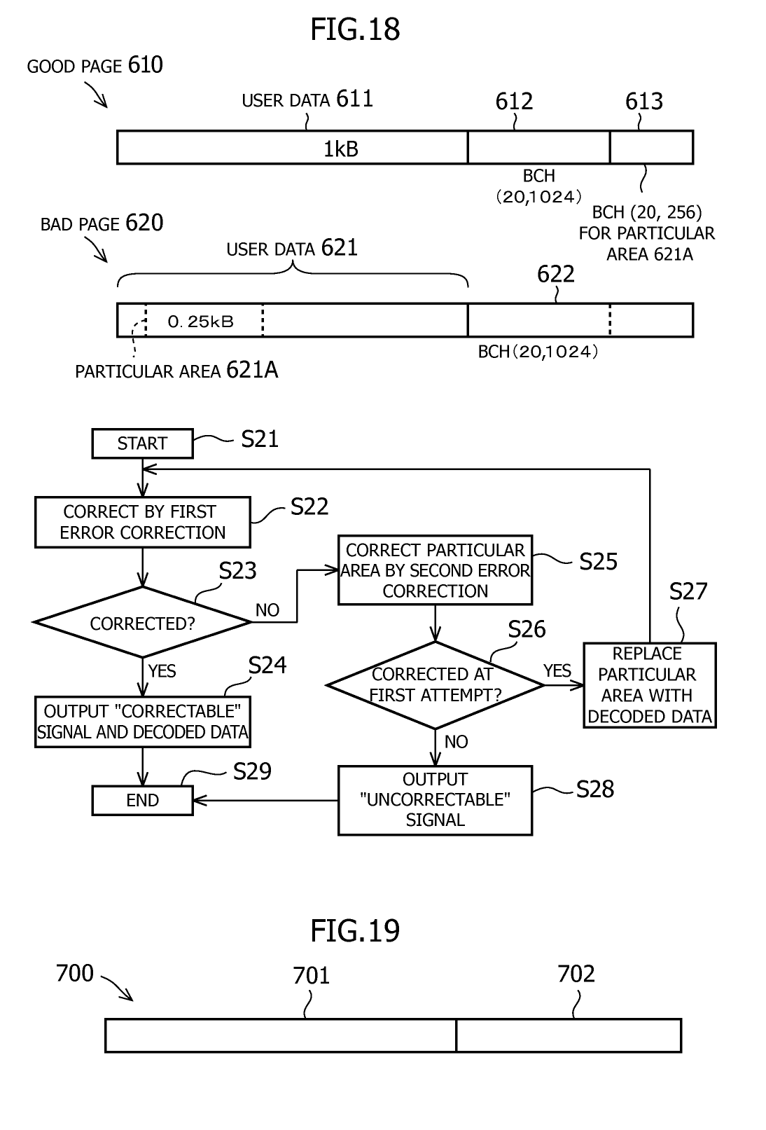

FIG. 18 is another modification example illustrating what procedure can be taken to apply the method of the present invention when there are the error correction unit 610 in a relatively low-error bit count page and the error correction unit 620 in a page having a relatively high error bit count. A user data area 611 and a user data area 621 are each 1 kB as in the example given above. Errors in an area within the relatively low-error bit count page are correctable by BCH (20, 1024). BCH (20, 1024) may not be capable of correcting errors in the user data area 621 which is in the area 620 within the page having a relatively high error bit count. Therefore, a particular area 621A which is 254 bytes in size is provided in the user data area 621, and redundant data for the particular area 621A is saved in an area 613 within a relatively low-error bit count page. The particular area 621A may be at the left end or right end of the user data area 620, or may be at an arbitrary point in the user data as illustrated in FIG. 18. The particular area 621A may be divided into a plurality of areas inside the user data area 620. The size of the particular area 621A can be arbitrary, but needs to be large enough to ensure that data in the particular area 621A is successfully corrected and large enough to contribute to the successful correction of errors in the entire user data area 621. Processing of this modification example starts in Step S21, and errors in the user data area 621 are corrected by the first error correction method (Step S22). When it is determined in Step S23 that user data is correctable, a signal indicating that the data has successfully been corrected and decoded user data are output (Step S24). The processing is then ended (Step S29). When it is determined in Step S23 that errors have not been corrected successfully, data in the particular area 621A is corrected by the second error correction method (Step S25). The second error correction method used in Step S25 is, for example, BCH (20, 256). When it is determined in Step S26 that data in the particular area 621A has successfully been corrected, the data in the particular area 621A within the user data area 621 is replaced with the decoded corrected data (Step S27). The correction in Step S22 is then performed on output user data of the user data area 621 which has partially been replaced. Step S23 is executed again to determine whether or not data is correctable. When it is determined in Step S23 that the data is correctable, a “correctable” signal and decoded data are output in Step S24 (Step S24). When it is determined in Step S23 that data has not been corrected successfully, data in the particular area 621A is corrected by the second error correction method again (that this correction is executable is already known), and it is determined in Step S26 that whether or not this correction is the first time correction by the second correction method. When it is determined that the correction is not the first time correction by the second correction method, a signal indicating that data is uncorrectable is output in Step S28, and the processing is ended (Step S29). The particular area 621A, which is provided in one user data area 621 in FIG. 18, may be divided into a plurality of areas to be placed in two or more user data areas. In this case, particular areas created by dividing a particular area are re-combined and the second correction method is applied to the particular area created by the re-combining.

The embodiment described above uses BCH codes in error correction. Other error correcting codes than BCH codes, such as Reed-Solomon codes and low-density parity-check codes, may be used. The correctable bit count, too, is not limited to the values given in the examples above.

In the embodiment described above, the proportion or count of error bits in one error correction unit can be used as a reference for determining whether the error correction unit contains many errors or few errors. If the count of error bits is to be used as the reference, the reference can be a mean value of the error bit counts of all error correction units in a block to which the error correction unit in question belongs, or a value obtained by adding a given figure to the mean value, or a mean value of maximum error bit counts and minimum error bit counts of the respective pages or error correction units in the relevant block. Alternatively, the reference for distinguishing whether there are many errors or few errors may be the count of error bits that can be corrected with the first set of redundant bits, and can be a basis for determining whether to use the second set of redundant bits. In setting the reference, a slight margin may be allowed to accommodate error characteristics deterioration with time of the NAND memory. The reference for distinguishing whether there are many errors or few errors may also be a suitable value set as a threshold at the design stage of the non-volatile memory.

What is claimed is:

1. A non-volatile semiconductor memory device having a storage area containing a plurality of pages, each of which includes at least one error correction unit comprising a user data area and a redundancy area,
wherein the redundancy area of the at least one error correction unit comprises:
a first redundancy area for storing a first set of redundant bits for correcting errors in the user data area within the error correction unit; and
a second redundancy area for storing a second set of redundant bits for correcting errors in the error correction unit in order to deal with a case where a relatively large number of errors in a first page to which the error correction unit belongs, so that the second set of redundant bits may be distributed between the error correction unit and an error correction unit in at least one different page which has a relatively small number of errors compared to the first page.

2. A non-volatile semiconductor memory device having a storage area containing a plurality of pages including a page having a relatively small number of errors and a page having a relatively large number of errors, each of the plurality of pages including at least one error correction unit which comprises a user data area and a redundancy area,
wherein the redundancy area of the at least one error correction unit found in at least one page having a relatively small number of errors comprises:
a first redundancy area for storing a first set of redundant bits for correcting errors that are in the user data area within the at least one error correction unit; and
a second redundancy area for storing at least part of a second set of redundant bits for correcting errors in an error correction unit that belongs to a page having a relatively large number of errors.

3. An error correction method for a non-volatile semiconductor memory device having a storage area containing a plurality of pages, each of which comprises at least one error correction unit comprising a user data area and a redundancy area,
wherein the redundancy area of the at least one error correction unit comprises:
a first redundancy area for storing a first set of redundant bits for correcting errors in the user data area within the error correction unit; and
a second redundancy area for storing a second set of redundant bits for correcting errors in the error correction unit when it is known that a relatively large number of errors exist in a page to which the error correction unit belongs, so that the second set of redundant bits may be distributed between the error correction unit and an error correction unit in a different page having a small number of errors compared to the page to which the error correction unit belongs,
the error correction method comprising the steps of:
correcting, with the first set of redundant bits, errors in user data of an error correction unit that belongs to a page having a relatively small number of errors; and
dividing a user data area for user data of an error correction unit that belongs to a page having a relatively large number of errors, and performing error correction on each area that is created by dividing the user data area with redundant bits in the second redundancy area.

4. An error correction method for a non-volatile semiconductor memory device having a storage area containing a plurality of pages comprising a page having a relatively small number of errors and a page having a relatively large number of errors, each of the plurality of pages including at least one error correction unit which comprises a user data area and a redundancy area,
wherein the redundancy area of at least one error correction unit found in at least one page having a relatively small number of errors comprises:
a first redundancy area for storing a first set of redundant bits for correcting errors that are in the user data area within the at least one error correction unit; and
a second redundancy area for storing a second set of redundant bits for correcting errors in an error correction unit that belongs to a page having a relatively large number of errors,
the error correction method comprising:
a first correction step of correcting errors in a user data area of an error correction unit that belongs to a page having a relatively small number of errors, with the first set of redundant bits in the error correction unit; and
a second correction step of dividing a user data area of an error correction unit that belongs to a page having a relatively large number of errors, and performing error correction on each area that is created by dividing the user data area, with the redundant bits in the second redundancy area or all or part of redundant bits in the error correction unit of the page having a relatively large number of errors or both.

5. An error correction method for a non-volatile semiconductor memory device having a storage area containing a plurality of pages comprising a page having a relatively small number of errors and a page having a relatively large number of errors, each of the plurality of pages including at least one error correction unit which comprises a user data area and a redundancy area,
wherein the redundancy area of at least one error correction unit found in at least one page having a relatively small number of errors comprises:
a first redundancy area for storing a first set of redundant bits for correcting errors that are in the user data area within the at least one error correction unit; and
a second redundancy area for storing a second set of redundant bits for correcting errors in an error correction unit that belongs to a page having a relatively large number of errors,
wherein the redundancy area of at least one error correction unit in at least one page having a relatively large number of errors stores at least one set of redundant bits for correcting errors in a user data area within the at least one error correction unit,
the error correction method comprising:
a first correction step of correcting errors in the user data area of the at least one error correction unit in the at least one page having a relatively large number of errors, with the at least one set of redundant bits in the at least one error correction unit;
a post-correction state determination step of determining whether or not the errors in user data within the at least one error correction unit have successfully been corrected in the first correction step; and
an error correction step of dividing, when it is determined in the post-correction state determination step that the errors have not been corrected successfully, the user data area of the at least one error correction unit, and performing error correction on each area that is created by dividing the user data area, with the redundant bits in the second redundancy area, or all or part of redundant bits other than those in the set of redundant bits found in the at least one error correction unit of the at least one page having a relatively large number of errors, or both.

6. An error correction method for a non-volatile semiconductor memory device having a storage area containing a plurality of pages comprising a page having a relatively small number of errors and a page having a relatively large number of errors, each of the plurality of pages including at least one error correction unit which comprises a user data area and a redundancy area,
wherein the user data area of at least one error correction unit in a page having a relatively large number of errors has a particular area,
wherein the redundancy area of at least one error correction unit that is in at least one page having a relatively smaller number of errors comprises:
a first redundancy area for storing a first set of redundant bits for correcting errors that are in the user data area within the at least one error correction unit; and
a second redundancy area for storing a second set of redundant bits for correcting errors in the particular area within an error correction unit that belongs to a page having a relatively large number of errors,
wherein the redundancy area of at least one error correction unit in at least one page having a relatively large number of errors stores at least one set of redundant bits for correcting errors in a user data area within the at least one error correction unit,
the error correction method comprising:
a first correction step of correcting errors in the user data area of the error correction unit in the page having a relatively large number of errors, with the at least one set of redundant bits in the error correction unit;
a post-correction state determination step of determining whether or not the errors in user data within the error correction unit have successfully been corrected in the first correction step;
an error correction step of applying the second set of redundant bits to the particular area when it is determined in the post-correction state determination step that the errors have not been corrected successfully; and
a second correction step of replacing data in the particular area with the corrected data of the particular area, and then correcting errors in the user data area that contains the replaced data, with the one set of redundant bits in the error correction unit.

7. The error correction method according to claim 4, further comprising, prior to the first correction step:
an error detection step of detecting a count of errors in the user data of the error correction unit; and
a step of determining whether or not the error count detected in the error detection step is within a range that is correctable in the first correction step, so as to proceed to the first correction step when the detected errors are correctable in the first correction step, and otherwise proceed to the second correction step.

8. The error correction method according to claim 7, wherein, in the error detection step, the user data and redundant bits are each converted into a balanced code in which a count of “0” bits and a count of “1” bits are made equal to each other, the balanced codes are written in and read out of the non-volatile semiconductor memory device, and a loss of balance between the count of “0” bits and the count of “1” bits is utilized to detect an error.

9. An error correction device for a non-volatile semiconductor memory device having a storage area containing a plurality of pages, each of which includes at least one error correction unit comprising a user data area and a redundancy area, the error correction device comprising:
first redundant bit writing means for storing, in an error correction unit, a first set of redundant bits for correcting errors in user data of that error correction unit;
second redundant bit writing means for storing a second set of redundant bits for correcting errors in the one error correction unit when a relatively large number of errors exist in the user data of the one error correction unit, so that the second set of redundant bits may be distributed between the one error correction unit and an error correction unit that belongs to a different page having a relatively small number of errors compared to a page to which the one error correction unit belongs;
first error correction executing means for correcting error bits in the one error correction unit with the first set of redundant bits;
post-correction state determining means for determining whether or not the first error correction executing means has succeeded in correcting the errors in the user data of the one error correction unit; and
second error correction executing means for using the second set of redundant bits to correct error bits in the one error correction unit when the post-correction state determining means determines that the errors have not been corrected successfully.

10. The error correction device according to claim 9, further comprising:
error detecting means for detecting a count of error bits in the one error correction unit; and
correction method determining means for determining whether or not the error bit count detected by the error detecting means is within a range that is correctable by the first error correction executing means,
wherein, when the correction method determining means determines that the detected errors are correctable by the first error correction executing means, the first error correction executing means executes error correction, and otherwise the second error correction executing means executes error correction.

11. The error correction device according to claim 10, wherein the error detecting means converts user data and redundant bits each into a balanced code in which a count of “0” bits and a count of “1” bits are made equal to each other, writes and reads the balanced codes in and out of the non-volatile semiconductor memory device, and utilizes a loss of balance between the count of “0” bits and the count of “1” bits to detect an error.
